(19) United States
(12) Patent Application Publication
(10) Pub. No.: US 2008/0262769 A1
(43) Pub. Date: Oct. 23, 2008

(54) USING MULTIVARIATE HEALTH METRICS TO DETERMINE MARKET SEGMENT AND TESTING REQUIREMENTS

(76) Inventors: DANIEL KADOSH, Austin, TX (US); Gregory A. Cherry, Kyle, TX (US); Carl L. Bowen, Austin, TX (US); Luis De La Fuente, Austin, TX (US); Rajesh Vijayaraghavan, Austin, TX (US)

Correspondence Address: WILLIAMS, MORGAN & AMERSON, 10333 RICHMOND, SUITE 1100, HOUSTON, TX, 77042, US

(21) Appl. No.: 11/738,540

(22) Filed: Apr. 23, 2007

(51) Int. Cl. G06F 11/30; G01R 31/26

(52) U.S. Cl. 702/82; 702/123

(57) ABSTRACT

A method includes receiving a first set of parameters associated with a particular die. A health metric for a particular die is determined using a multivariate analysis of the first set of parameters. The health metric incorporates at least one performance metric. At least one of a market segment designator or a testing plan associated with the particular die is determined based on the health metric.

### CROSS-REFERENCE TO RELATED APPLICATIONS

Not applicable.

### BACKGROUND OF THE INVENTION

The present invention relates generally to manufacturing and testing of semiconductor devices, more particularly, to using multivariate health metrics to determine market segment and testing requirements.

There is a constant drive within the semiconductor industry to increase the quality, reliability and throughput of integrated circuit devices, e.g., microprocessors, memory devices, and the like. This drive is fueled by consumer demands for higher quality computers and electronic devices that operate more reliably. These demands have resulted in a continual improvement in the manufacture of semiconductor devices, e.g., transistors, as well as in the manufacture of integrated circuit devices incorporating such transistors. Additionally, reducing the defects in the manufacture of the components of a typical transistor also lowers the overall cost of integrated circuit devices incorporating such transistors.

Generally, a distinct sequence of processing steps is performed on a lot of wafers using a variety of processing tools, including photolithography steppers, etch tools, deposition tools, polishing tools, rapid thermal processing tools, implantation tools, etc., to produce final products that meet certain electrical performance requirements. In some cases, electrical measurements that determine the performance of the fabricated devices are not conducted until relatively late in the fabrication process, and sometimes not until the final test stage.

During the fabrication process various events may take place that affect the end performance of the devices being fabricated. That is, variations in the fabrication process steps result in device performance variations. Factors, such as feature critical dimensions, doping levels, contact resistance, particle contamination, etc., all may potentially affect the end performance of the device. Devices are typically ranked by a grade measurement, which effectively determines its market value. In general, the higher a device is graded, the more valuable the device.

The electrical tests performed after the fabrication of the device determine its final grade and functionality. A wide variety of tests may be performed. Exemplary tests include: final wafer electrical tests (FWET) that evaluate discrete test structures like transistors, capacitors, resistors, interconnects and relatively small and simple circuits, such as ring oscillators at various sites on a wafer; sort tests that sort die into bins (categories of good or bad) after testing functionality of each die; burn-in tests that test packaged die under temperature and/or voltage stress; automatic test equipment (ATE) tests that test die functionality using a test protocol that is a superset of sort; and system-level tests (SLT) that test packaged die in an actual motherboard by running system-level tests (e.g., booting the operating system).

The variety of electrical tests that devices must undergo consume considerable metrology resources, and may present a production bottleneck. Due to the complexity of integrated circuit devices, and the costs associated with screening devices to identify which are most at-risk, it is often difficult to identify the populations at risk for which increased metrology should be provided. Typically, fixed metrology sampling plans are employed for electrical testing. Such fixed sampling plans may, in some cases, result in reduced efficiency by implementing excessive testing, while in other cases, may result in the failure to adequately identify faulty devices.

This section of this document is intended to introduce various aspects of art that may be related to various aspects of the present invention described and/or claimed below. This section provides background information to facilitate a better understanding of the various aspects of the present invention. It should be understood that the statements in this section of this document are to be read in this light, and not as admissions of prior art. The present invention is directed to overcoming, or at least reducing the effects of, one or more of the problems set forth above.

### BRIEF SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

One aspect of the present invention is seen in a method that includes receiving a first set of parameters associated with a particular die. A health metric for a particular die is determined using a multivariate analysis of the first set of parameters. The health metric incorporates at least one performance component. At least one of a market segment designator or a testing plan associated with the particular die is determined based on the health metric.

Another aspect of the present invention is seen in a method that includes receiving a first set of parameters associated with a particular die. A health metric is determined for the particular die using a multivariate analysis of the first set of parameters. A market segment designator for the particular die is determined based on the health metric.

Yet another aspect of the present invention is seen in a method that includes receiving a first set of parameters associated with a particular die. A health metric is determined for the particular die using a multivariate analysis of the first set of parameters. The health metric incorporates at least one performance component. A testing plan associated with the particular die is determined based on the health metric.

### BRIEF DESCRIPTION OF THE SEVERAL VIEWS OF THE DRAWINGS

The invention will hereafter be described with reference to the accompanying drawings, wherein like reference numerals denote like elements, and:

FIG. 1 is a simplified block diagram of a manufacturing system in accordance with one illustrative embodiment of the present invention;

FIG. 2 is a diagram of a wafer map used for data expansion by the die health unit of FIG. 1;

FIG. 3 is a diagram illustrating a hierarchy used by the die health unit of FIG. 1 for grouping SORT and FWET test parameters for determining die performance; and

FIG. 4 is a diagram of a hierarchy including neighborhood performance metrics.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

One or more specific embodiments of the present invention will be described below. It is specifically intended that the present invention not be limited to the embodiments and illustrations contained herein, but include modified forms of those embodiments including portions of the embodiments and combinations of elements of different embodiments as come within the scope of the following claims. It should be appreciated that in the development of any such actual implementation, as in any engineering or design project, numerous implementation-specific decisions must be made to achieve the developers' specific goals, such as compliance with system-related and business related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure. Nothing in this application is considered critical or essential to the present invention unless explicitly indicated as being “critical” or “essential.”

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Portions of the present invention and corresponding detailed description are presented in terms of software, or algorithms and symbolic representations of operations on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” or “accessing” or “displaying” or the like, refer to the action and processes of a computer system, or similar electronic computing device, that manipulates and transforms data represented as physical, electronic quantities within the computer system's registers and memories into other data similarly represented as physical quantities within the computer system memories or registers or other such information storage, transmission or display devices. Note also that the software implemented aspects of the invention are typically encoded on some form of program storage medium or implemented over some type of transmission medium. The program storage medium may be magnetic (e.g., a floppy disk or a hard drive) or optical (e.g., a compact disk read only memory, or “CD ROM”), and may be read only or random access. Similarly, the transmission medium may be twisted wire pairs, coaxial cable, optical fiber, or some other suitable transmission medium known to the art. The invention is not limited by these aspects of any given implementation.

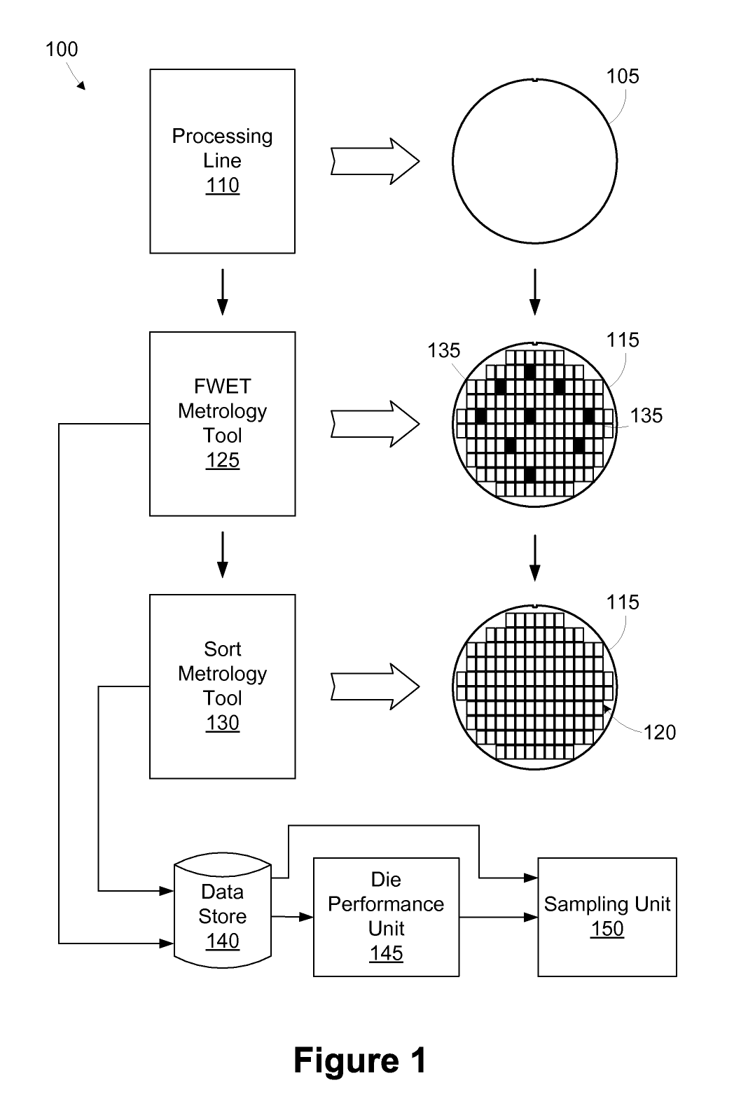

Referring now to the drawings wherein like reference numbers correspond to similar components throughout the several views and, specifically, referring to FIG. 1, the present invention shall be described in the context of a manufacturing system 100. The manufacturing system includes a processing line 110, one or more final wafer electrical test (FWET) metrology tools 125, one or more SORT metrology tools 130, a data store 140, a die health unit 145, a sampling unit 150. In the illustrated embodiment, a wafer 105 is processed by the processing line 110 to fabricate a completed wafer 115 including at least partially completed integrated circuit devices, each commonly referred to as a die 120. The processing line 110 may include a variety of processing tools (not shown) and/or metrology tools (not shown), which may be used to process and/or examine the wafer 105 to fabricate the semiconductor devices. For example, the processing tools may include photolithography steppers, etch tools, deposition tools, polishing tools, rapid thermal anneal tools, ion implantation tools, and the like. The metrology tools may include thickness measurement tools, scatterometers, ellipsometers, scanning electron microscopes, and the like. Techniques for processing the wafer 105 are well known to persons of ordinary skill in the art and therefore will not be discussed in detail herein to avoid obscuring the present invention. Although a single wafer 105 is pictured in FIG. 1, it is to be understood that the wafer 105 is representative of a single wafer as well as a group of wafers, e.g. all or a portion of a wafer lot that may be processed in the processing line 110.

After the wafer 105 has been processed in the processing line 110 to fabricate the completed wafer 115, the wafer 115 is provided to the FWET metrology tool 125. The FWET metrology tool 125 gathers detailed electrical performance measurements for the completed wafer 115. Final wafer electrical testing (FWET) entails parametric testing of discrete structures like transistors, capacitors, resistors, interconnects and relatively small and simple circuits, such as ring oscillators. It is intended to provide a quick indication as to whether or not the wafer is within basic manufacturing specification limits. Wafers that exceed these limits are typically discarded so as to not waste subsequent time or resources on them.

For example, FWET testing may be performed at the sites 135 identified on the wafer 115. In one embodiment, FWET data may be collected at one or more center sites and a variety of radial sites around the wafer 115. Of course, the number and distribution of FWET sites may vary depending on the particular implementation. Exemplary FWET parameters include, but are not limited to, diode characteristics, drive current characteristics, gate oxide parameters, leakage current parameters, metal layer characteristics, resistor characteristics, via characteristics, etc. The particular FWET parameters selected may vary depending on the application and the nature of the device formed on the die.

Table 1 below provides an exemplary, but not exhaustive, list of the types of FWET parameters collected (i.e., designated by “(F)” following the parameter description).

Following FWET metrology, the wafers 115 are provided to the SORT metrology tool 130. At SORT, individual dies are tested for functionality, which is a typically much longer and more involved test sequence than FWET, especially in the case of a microprocessor. The SORT metrology tool 130 employs a series of probes to electrically contact pads on the completed die 120 to perform electrical and functional tests. For example, the SORT metrology tool 130 may measure voltages and/or currents between various nodes and circuits that are formed on the wafer 115. Exemplary SORT parameters measured include, but are not limited to, clock search parameters, diode characteristics, scan logic voltage, static IDD, VDD min, power supply open short characteristics, and ring oscillator frequency, etc. The particular SORT parameters selected may vary depending on the application and the nature of the device formed on the die. Table 1 below provides an exemplary, but not exhaustive, list of the types of SORT parameters collected (i.e., designated by “(S)” following the parameter description). Typically, wafer SORT metrology is performed on each die 120 on the wafer 115 to determine functionality and baseline performance data.

TABLE 1
Die Performance Parameters

| Block | Category | Type | Parameter |
|---|---|---|---|
| PMIN | VDDmin | Scan Logic | Minimum Voltage (S) |
| | | BIST | Minimum Voltage (S) |
| LEAK | Gate Oxide | NOxide | Oxide Thickness (F) |
| | | POxide | Oxide Thickness (F) |
| | Leakage | NLeak | Leakage Current (F) |
| | | PLeak | Leakage Current (F) |
| | | SSID | Static IDD (S) |
| | | NJunction | N Junction |
| | | | Parameters (F) |
| | Drive | NDrive | Drive Current (F) |
| | | PDrive | Drive Current (F) |
| YIELD | Metal | Metal 1 | Various Resistance |
| | | | (F) |
| | | | Various Leakage (F) |
| | | . | |
| | | . | |
| | | . | |
| | | Metal n | Various Resistance |
| | | | (F) |
| | | | Various Leakage (F) |
| | Open Short | VDD Short | Resistance, |
| | | | Continuity, and Short |
| | | | Parameters (F, S) |
| | | VtShort | Resistance, |
| | | | Continuity, and Short |
| | | | Parameters (F, S) |
| | Via | Via 1 | Resistance (F) |
| | | . | |
| | | . | |
| | | . | |
| | | Via n | Resistance (F) |
| | Clock | Clock Search | Clock Edge |
| | | | Parameters (S) |
| | Bin Result | Test Classifier | Fail Type Indicator |
| SPEED | Resistor | NPoly | Resistance (F) |
| | | NRes | Resistance (F) |
| | RO | RO Freq | Ring Oscillator |
| | | | Frequency (S) |
| | | RO Pass/Fail | Pass/Fail (S) |
| | Miller | NMiller | Miller Capacitance (F) |
| | | PMiller | Miller Capacitance (F) |
| | Diode | Ideality | Thermal Diode |
| | | | Parameters (S) |
| | | Thermal Diode | Thermal Diode |
| | | | Measurements (S) |

The results of the SORT and FWET testing may be stored in the data store 140 for further evaluation. In one embodiment of the invention, the SORT and FWET data are employed to generate health metrics for each of the die 120 on the wafer 115, as described in greater detail below. Health metrics may include performance components that relate to the performance of the device or yield components that relate to the ability of the device to function.

As described in greater detail below, the health metrics associated with neighboring die may also be incorporated into the final die health metric for a given die. Health metrics are generally based on multivariate groupings of parameters. Generally, the performance metrics evaluate performance for at least one non-yield related performance characteristic. For example, speed, minimum voltage, and leakage metrics are representative non-yield performance metrics. As described in greater detail below, a yield metric may be considered in conjunction with the performance metrics to determine an overall health metric. To generate die health metrics for each individual die, in accordance with the illustrated embodiment, both SORT and FWET data are used. However, because FWET data is not collected for each site, estimated FWET parameters are generated for the non-measured sites by the die health unit 145.

As described in greater detail below, a die health model, such as a principal component analysis (PCA) model, is used by the die health unit 145 to generate a preliminary die health metric for each die based on the collected SORT data and collected and estimated FWET data. For the untested die, the SORT and estimated FWET data are used to generate die health metrics, while for the tested die, the SORT and measured FWET data are employed to generate die health metrics.

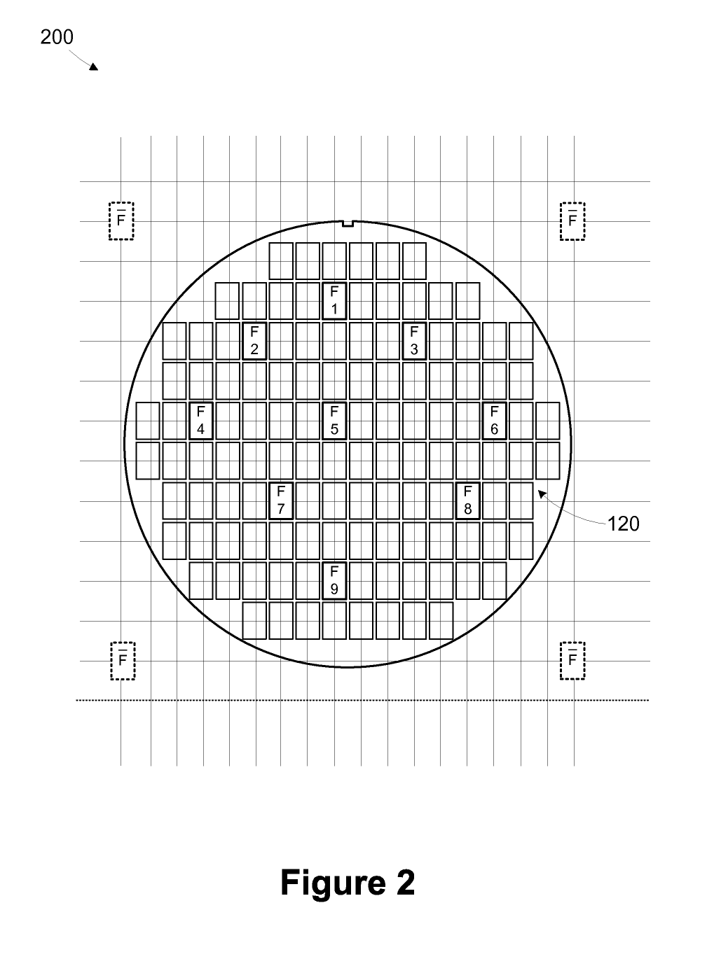

Turning now to FIG. 2, a diagram illustrating a wafer map 200 used by the die health unit 145 to generate estimated FWET data for unmeasured die is shown. In the illustrated embodiment, a splined interpolation is used to estimate the FWET parameters for the untested die. A separate splined interpolation may be performed for each FWET parameter measured. Prior to the interpolation, the FWET data may be filtered using techniques as a box filter or sanity limits to reduce noise in the data.

The splined interpolation considers the actual measured FWET parameter values at the tested die locations, as represented by sites F1-F8 in FIG. 2. To facilitate the splined interpolation, derived data points, F̅, are placed at various points on the wafer map 200 outside the portion that includes the wafer. The F̅ values represent the wafer mean value for the FWET parameter being interpolated. In the example wafer map 200 of FIG. 2, the wafer mean values, F̅, are placed at the diagonal corners of the wafer map 200. In other embodiment, different numbers or different placements of wafer mean values may be used on the wafer map 200. Other statistics, such as median values may also be used. The output of the splined interpolation is a function that defines estimated FWET parameter values at different coordinates of the grid defining the wafer map 200. Other aggregate statistics, such as median values may also be used for the splined interpolation.

A splined interpolation differs from a best-fit interpolation in that the interpolation is constrained so that the curve passes through the observed data points. Hence, for the tested die, the value of the splined interpolation function at the position of the tested die matches the measured values for those die. Due to this correspondence, when employing the splined interpolation, the interpolation function may be used for both tested and untested die, thus simplifying further processing by eliminating the need to track which die were tested.

The particular mathematical steps necessary to perform a splined interpolation are known to those of ordinary skill in the art. For example, commercially available software, such as MATLAB®, offered by The MathWorks, Inc. of Natick, Mass. includes splined interpolation functionality.

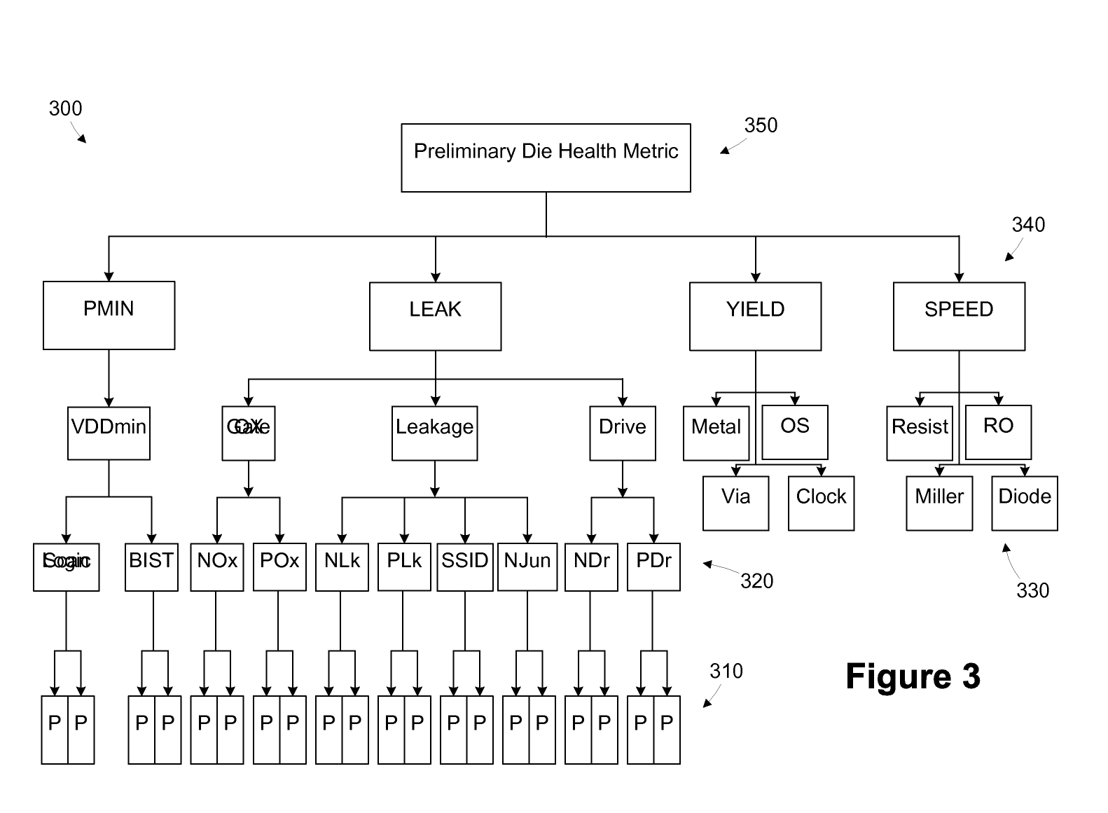

Following the data expansion, the die health unit 145 generates a preliminary die health metric for each die 120. The parameters listed in Table 1 represent univariate inputs to a model that generates a die health metric for a given die using only parameters associated with that die. The block, category, and type groupings represent multivariate grouping of the parameters. FIG. 3 illustrates an exemplary hierarchy 300 for the model using the parameters and groupings illustrated in Table 1 for generating preliminary health metric information. Only a subset of the parameter types and categories are illustrated for ease of illustration. The hierarchy 300 includes a parameter level 310 representing individual parameters gathered during the SORT and FWET tests. In the case of the FWET parameters, the data expansion described above is used to generate estimated FWET parameters for the untested die.

A first grouping of parameters 310 is employed to generate a type level 320, and multiple types may be grouped to define a category level 330. Multiple categories may be grouped to define a block level 340. The combination of the block level 340 groupings defines a preliminary die health metric 350 for the given die 120. In the illustrated embodiment, the PMIN block includes a VDDmin category and scan logic and BIST types. The leakage block includes gate oxide, leakage, and drive categories, with the type groupings shown. The yield block includes metal, open short, via, clock, and bin result categories. The speed block includes resistor, ring oscillator, Miller, and diode categories. For ease of illustration, the types and parameters are not illustrated for the yield and speed blocks, as they may be similarly grouped using the hierarchy 300 in view of Table 1. Again, the particular parameters 310, number of blocks 340, categories 330, and types 320 are intended to be illustrative and not to limit the present invention. In alternative embodiments, any desirable number of hierarchy layers may be chosen, and each layer may be grouped into any desirable number of groups. Again, the speed, leakage, and PMIN health metrics are considered non-yield performance metrics that may be combined with the yield metric to determine the overall die health.

In the illustrated embodiment, the values of the block groupings may also represent health metrics themselves, or may be considered as components of the overall die health metric. Hence, a health metric may be defined as one of the blocks 340 or the overall die health metric 350.

In some embodiments, the preliminary die health metric 350 may be used as a screening metric. If a predetermined percentage of the die on the wafer have preliminary die health metrics 350 over a predetermined threshold, all of the die may be assigned to a common market segment and burn-in testing may be skipped. For example, if >90% have a preliminary die health metric 350 above the health threshold, the die may all be assigned a market segment designator based on mean performance metrics (e.g., speed, leakage, PMIN) for the wafer. For example, the market segment rules illustrated below in FIG. 2 may be applied to the wafer mean values of the performance metrics to determine the designator for the entire lot (e.g., mobile or desktop). Because of the high confidence associated with the relatively high health metrics 350, it is reasonable to skip burn-in testing for the devices, thereby increasing efficiency in terms of processing as well as metrology resources.

If the distribution of preliminary die health metrics 350 does not indicate that the majority of die health have high health metrics 350, the die may be further segmented for purposes of subsequent testing or market segment using additional analysis. One technique for further analysis involves considering the health metrics of neighboring die.

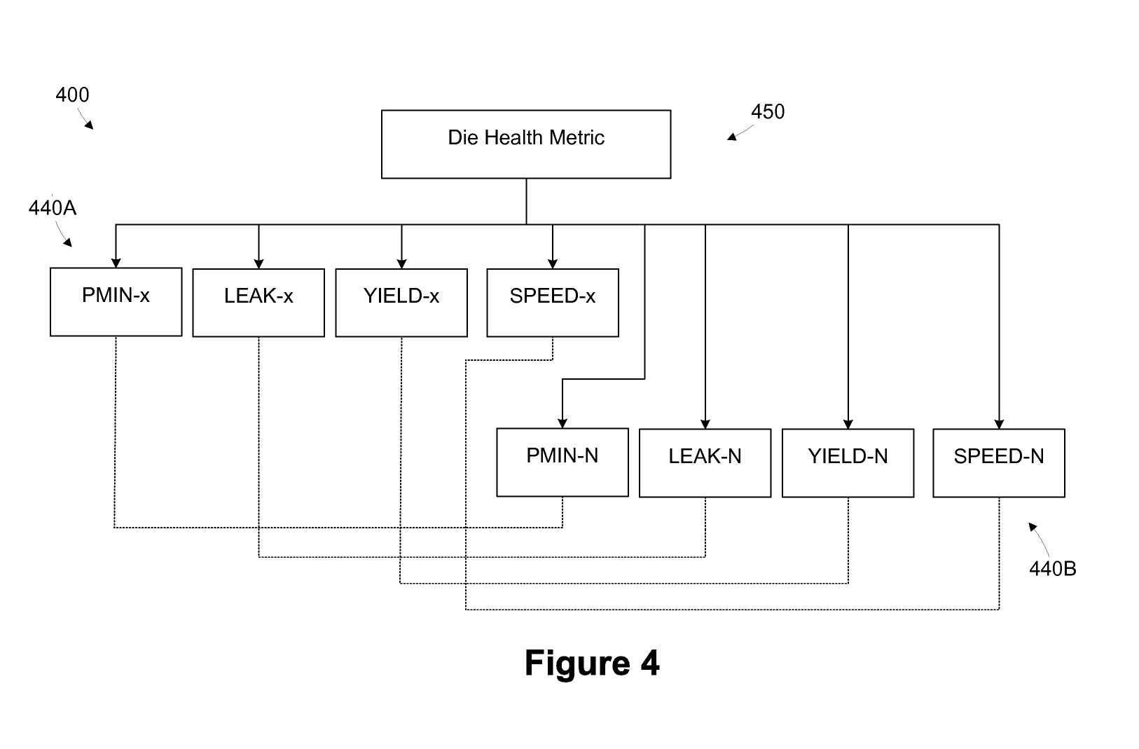

Referring now to FIG. 4, a second hierarchy 400 is illustrated that incorporates the individual health metrics 440A (i.e., designated by die-x) generated in accordance with the hierarchy of FIG. 3 with corresponding health metrics 440B for neighboring die (i.e., designated by neighbor-N) into the die health metric 450. To implement the hierarchy 400 of FIG. 4, the die health unit 145 first determines the health metrics (e.g., performance and yield) for each die in a set (e.g., wafer or lot). The die health unit 145 then determines which die are considered neighboring die for a given die and generates the neighborhood block metrics 440B for that subset. For example, the neighborhood health metrics 440B may be determined by averaging the individual health metrics for the die in the neighborhood. Subsequently, the die health unit 145 runs the die health model again using the parameters 440A associated with the given die and the parameters 440B determined for its neighbors. Although only the block level parameters 440A are illustrated, the die health unit 145 may also apply the model using the other levels of the hierarchy 300 shown in FIG. 3.

In FIG. 4, the neighborhood metrics 440B are illustrated in the hierarchy below the overall die health metric 450. In some embodiments, the neighborhood metrics 440B are incorporated into the individual health metrics 440A. For example, the SPEED neighborhood metric may be incorporated into the corresponding SPEED metric or the LEAKAGE neighborhood metric may be incorporated into the LEAKAGE metric as indicated by the dashed lines in FIG. 4.

The particular groupings the die health unit 145 may use for identifying neighboring die may vary. Exemplary die neighborhood designations may include the die immediately surrounding the given die, the die positioned at the same radial position from the center of the wafer, the die in the same position in a lithography reticle cluster, and the die from other wafers in the same lot that are in the same x-y position on the wafer grid. Of course, other neighborhoods may be defined, depending on the particular embodiment and the nature of the devices being fabricated. Although only a single set of neighborhood metrics are illustrated in FIG. 4, it is contemplated that multiple neighborhoods may be used. For example, neighborhood metrics may be determined for each of the possible neighborhood groupings listed, and all the neighborhood metrics may contribute toward the overall health metric for the given die.

The die health unit 145 may report both the preliminary die health metric 350 for the given die, as well as the neighborhood-adjusted die health metric 450 for comparison purposes. For example, if the preliminary die health metric 350 indicates a die with relatively high die health, the test requirements might have been lowered for that die if no other factors were considered. However, if the neighborhood-adjusted die health metric 450 indicates that the degree of certainty of the individual die health metric is suspect as the die in the same neighborhood do not have consistently high health metrics, more aggressive burn-in testing may be warranted to stress the die and verify its level of performance.

Residual values may be determined by comparing the health metrics 440A to the neighborhood health metrics 440B. The size of the residuals represent the distance between the selected die and the others in its neighborhood grouping. Rather than repeating the model, the die health unit 145 may adjust the preliminary die health metric 350 based on the size of the residuals to generate the overall die health metric 450. If the residuals were small, it would indicate that the subject die is consistent with its neighbors and that the preliminary die health metric 350 may be accurate. On the other hand, large residuals would indicate a higher degree of uncertainty with respect to the preliminary die health metric 350, resulting in a lowering of the overall die health metric 450.

One type of model that may be used, as described in greater detail below, is a recursive principal component analysis (RPCA) model. Health metrics are calculated by comparing data for all parameters from the current die and the neighboring die to a model built from known-good die. For an RPCA technique, this metric is the φᵣ statistic, which is calculated for every node in the hierarchy, and is a positive number that quantitatively measures how far the value of that node is within or outside 2.8-σ of the expected distribution. The nodes of the hierarchy include an overall die health metric 450 for the die, and the various blocks 440, categories 430, types 420 and univariates for individual FWET and SORT parameters 410. These φᵣ values and all die-level results plus their residuals are stored in the data store 140 by the die health unit 145.

Although the application of the present invention is described as it may be implemented using a RPCA model, the scope is not so limited. Other types of multivariate statistics-based analysis techniques that consider a large number of parameters and generate a single quantitative metric (i.e., not just binary) indicating the “goodness” of the die may be used. For example, one alternative modeling technique includes a k-Nearest Neighbor (KNN) technique.

Principal component analysis (PCA), of which RPCA is a variant, is a multivariate technique that models the correlation structure in the data by reducing the dimensionality of the data. A data matrix, X, of n samples (rows) and m variables (columns) can be decomposed as follows:

X=\hat{X}+\tilde{X}, (1)

where the columns of X are typically normalized to zero mean and unit variance. The matrices \hat{X} and \tilde{X} are the modeled and unmodeled residual components of the X matrix, respectively. The modeled and residual matrices can be written as

\hat{X}=TP^{T} and \tilde{X}=\tilde{T}\tilde{P}^{T} (2)

where Tε [symbol] ^{n×l} and Pε [symbol] ^{n×l} are the score and loading matrices, respectively, and l is the number of principal components retained in the model. It follows that \tilde{T} ε [symbol] ^{n×(m-l)} and \tilde{P} ε [symbol] ^{m×(m-l)} are the residual score and loading matrices, respectively.

The loading matrices, P and \tilde{P}, are determined from the eigenvectors of the correlation matrix, R, which can be approximated by

$$R \approx \frac{1}{n - 1} {X}^{T} X . \qquad ( 3 )$$

The first l eigenvectors of R (corresponding to the largest eigenvalues) are the loadings, P, and the eigenvectors corresponding to the remaining m−l eigenvalues are the residual loadings, \tilde{P}.

The number of principal components (PCs) retained in the model is an important factor with PCA. If too few PCs are retained, the model will not capture all of the information in the data, and a poor representation of the process will result. On the other hand, if too many PCs are chosen, then the model will be over parameterized and will include noise. The variance of reconstruction error (VRE) criterion for selecting the appropriate number of PCs is based on omitting parameters and using the model to reconstruct the missing data. The number of PCs which results in the best data reconstruction is considered the optimal number of PCs to be used in the model. Other, well-established methods for selecting the number of PCs include the average eigenvalues method, cross validation, etc.

A variant of PCA is recursive PCA (RPCA). To implement an RPCA algorithm it is necessary to first recursively calculate a correlation matrix. Given a new vector of unscaled measurements, xₖ₊₁⁰, the updating equation for the correlation matrix is given by

Rₖ₊₁=μΣₖ₊₁⁻¹(ΣₖRₖΣₖ+Δbₖ₊₁Δbₖ₊₁^{T})Σₖ₊₁⁻¹+(1−μ)xₖ₊₁xₖ₊₁^{T}, (4)

where xₖ₊₁ is the scaled vector of measurements, b is a vector of means of the data, and Σ is a diagonal matrix with the i^{th} element being the standard deviation of the i^{th} variable. The mean and variance are updated using

bₖ₊₁=μbₖ+(1−μ)xₖ₊₁⁰, and (5)

σₖ₊₁²(i)=μ(σₖ²(i)+Δbₖ₊₁²(i))+(1−μ)×∥xₖ₊₁⁰(i)−bₖ₊₁(i)∥². (6)

The forgetting factor, μ, is used to weight more recent data heavier than older data. A smaller μ discounts data more quickly.

After the correlation matrix has been recursively updated, calculating the loading matrices is performed in the same manner as ordinary PCA. It is also possible to employ computational shortcuts for recursively determining the eigenvalues of the correlation matrix, such as rank-one modification.

Die performance prediction using PCA models is accomplished by considering two statistics, the squared prediction error (SPE) and the Hotelling's T² statistic. These statistics may be combined to generate a combined index, as discussed below. The SPE indicates the amount by which a process measurement deviates from the model with

SPE=x^{T}(I−PP^{T})x=x^{T}Φ_{SPE}x, (7)

where

Φ_{SPE}=I−PP^{T}. (8)

Hotelling's T² statistic measures deviation of a parameter inside the process model using

T²=x^{T}PΛ⁻¹P^{T}x=x^{T}Φ_{T}_{²}x, (9)

where

Φ_{T}_{²}=PΛ⁻¹P^{T}, (10)

and Λ is a diagonal matrix containing the principal eigenvalues used in the PCA model. The notation using Φ_{SPE} and Φ_{T}_{²} is provided to simplify the multiblock calculations included in the next section. The process is considered normal if both of the following conditions are met:

SPE≦δ²,

T²≦χₗ² (11)

where δ² and Xₗ² are the confidence limits for the SPE and T² statistics, respectively. It is assumed that x follows a normal distribution and T² follows a X² distribution with l degrees of freedom.

The SPE and T² statistics may be combined into the following single combined index for the purpose of determining the die health metric

$$\begin{matrix}ϕ = \frac{SPE ( x )}{{δ}^{2}} + \frac{{T}^{2} ( x )}{{χ}_{l}^{2}} = {x}^{T} Φ x , \\ where & ( 12 ) \\ Φ = \frac{P {Λ}^{- 1} {P}^{T}}{{χ}_{l}^{2}} + \frac{I - {PP}^{T}}{{δ}^{2}} . & ( 13 )\end{matrix}$$

The confidence limits of the combined index are determined by assuming that φ follows a distribution proportional to the X² distribution. It follows that φ is considered normal if

φ≦gχ_{α}²(h), (14)

where α is the confidence level. The coefficient, g, and the degrees of freedom, h, for the X² distribution are given by

$$\begin{matrix}g = \frac{{tr ( R Φ )}^{2}}{tr ( R Φ )} , and & ( 15 ) \\ h = \frac{{[ tr ( R Φ ) ]}^{2}}{{tr ( R Φ )}^{2}} . & ( 16 )\end{matrix}$$

To provide an efficient and reliable method for grouping sets of variables together and identifying the die performance, a multiblock analysis approach may be applied to the T² and SPE. The following discussion describes those methods and extends them to the combined index. Using an existing PCA model, a set of variables of interest x_{b} can be grouped into a single block as follows:

x^{T}=[x₁^{T} . . . x_{b}^{T} . . . x_{B}^{T}]. (17)

The variables in block b should have a distinct relationship among them that allows them to be grouped into a single category for die performance purposes. The correlation matrix and Φ matrices are then partitioned in a similar fashion.

$$\begin{matrix}R = [ \begin{matrix}{R}_{1} & & & & \\ & ⋰ & & & \\ & & {R}_{b} & & \\ & & & ⋰ & \\ & & & & {R}_{B}\end{matrix} ] & ( 18 ) \\ Φ = [ \begin{matrix}{Φ}_{1} & & & & \\ & ⋰ & & & \\ & & {Φ}_{b} & & \\ & & & ⋰ & \\ & & & & {Φ}_{B}\end{matrix} ] & ( 19 )\end{matrix}$$

The contributions associated with block b for the SPE and T² and extended here to the combined index can be written as

T_{b}²=x_{b}^{T}Φ_{T}_{_{b}}_{²}x_{b} (20)

SPE_{b}=x_{b}^{T}Φ_{SPE}_{_{b}}x_{b} (21)

φ_{b}=x_{b}^{T}Φ_{φ}_{_{b}}x_{b}. (22)

The confidence limits for each of these quantities are calculated by modifying Equations 14, 15, and 16 to incorporate the multiblock quantities. While defined for the combined index, similar calculations hold for SPE and T².

$$\begin{matrix}{g}_{{ϕ}_{b}} = \frac{{tr ( {R}_{b} {Φ}_{{ϕ}_{b}} )}^{2}}{tr ( {R}_{b} {Φ}_{{ϕ}_{b}} )} & ( 23 ) \\ {h}_{{ϕ}_{b}} = \frac{{[ tr ( {R}_{b} {Φ}_{{ϕ}_{b}} ) ]}^{2}}{{tr ( {R}_{b} {Φ}_{{ϕ}_{b}} )}^{2}} & ( 24 ) \\ {ϕ}_{b , lim} = {g}_{{ϕ}_{b}} {χ}^{2} ( {h}_{{ϕ}_{b}} ) & ( 25 )\end{matrix}$$

The combined index used as the die health metric is defined by:

$${ϕ}_{r} = {ϕ}_{b , r} = {log}_{10} ( \frac{{ϕ}_{b}}{{ϕ}_{b , lim}} ) + 1. \qquad ( 26 )$$

By incorporating the health metrics associated with neighboring die into an overall die health metric for a particular die, the certainty associated with the overall die health metric may be increased. For example, if a preliminary die health metric 350 for a given die indicates a relatively high performance, but the health metrics 440B associated with the neighboring die indicate a lower performance, the value of the preliminary die health metric 350 may be suspect. The individual die may have performed well during the SORT testing, but latent issues may be present with the die that may only become apparent after a period of use. The degree of uncertainty with the preliminary die health metric 350 may be suggested by the neighborhood health metrics 440B. This degree of uncertainty results in a lowering of the overall die health metric 450 determined by incorporating the neighborhood health metrics 440B. If there is no such mismatch between the preliminary die health metric 350 and the neighborhood health metrics 440B, the confidence level of the of preliminary die health metric 350 is higher, and the overall die health metric 450 would not be lowered relative to the preliminary die health metric 350 based on the contribution of the neighborhood health metrics 440B.

The health metrics 350, 440A, 440B, 450 computed for the die 120 may be used for various purposes. In one embodiment, the health metrics are employed by the sampling unit 150 to determine subsequent testing requirements, such as burn-in. To decide which die undergo burn-in, the sampling unit 150 uses die performance thresholds in combination with other known characteristics of the die 120, such as bin classification.

The die performance information may also be considered in determining the market segment for the die 120. For example, in the case where the semiconductor devices are microprocessors, the packaged devices may be designated for use in a server, desktop computer, or mobile computer depending on the determined die performance.

The die health unit 145 may implement various rules for determining test requirements and/or market segment based on the health metrics 350, 440A, 440B, 450. Table 2 below illustrates exemplary rules for determining market segment and burn-in test requirements.

TABLE 2
Market Segment and Burn-in Test Rules

| | Server | Mobile | | | Desktop | | | |
|---|---|---|---|---|---|---|---|---|
| | BI | SKIP BI | RED BI | BI | SKIP BI | RED BI | BI | Scrap |
| YIELD | <Y₁ | <Y₁ | >Y₁, <Y₂ | >Y₁, <Y₃ | <Y₁ | >Y₁, <Y₂ | >Y₁, <Y₃ | >Y₃ |
| LEAK | <L₂ | <L₁ | <L₁ | <L₂ | <L₂ | <L₂ | <L₂ | >L₂ |
| SPEED | <Sₛ | <Sₛ | <Sₛ | <Sₛ | <Sₛ | <Sₛ | <Sₛ | >Sₛ |
| PMIN | <Vₛ | <V₁ | <V₁ | <V₁ | <Vₛ | <Vₛ | <Vₛ | <Vₛ |

The various thresholds illustrated in Table 2 are exemplary and may vary depending on the particular embodiment. Based on the determined die health metric and the exemplary rules listed in Table 2, the die health unit 145 may determine the market segment assigned to each die and/or the burn-in test requirements. If particular die health metrics are above certain thresholds, the die may be scrapped, as illustrated in Table 2. As specified by Table 2, multiple levels of burn-in may be specified. For example, the thresholds may be used to identify die 120 that should be subjected to a less strenuous burn-in (e.g., lower temperature or reduced time). The die health information may also be used to skip or reduce other types of testing for example, if the die health is greater than a particular threshold, reduced ATE testing may be performed and the device may pass to system level testing more quickly.

In general a testing plan may be specified for the die on the wafer depending on the die health metrics 350, 450. For example, if the wafer passes the screening test mentioned above (i.e., a percentage of the die exceed a health threshold based on the preliminary health metric 350), the testing plan may specify that burn-in testing is to be skipped and the die are to proceed to ATE or reduced ATE testing, followed by system level testing. In other cases, the testing plan may specify full or reduced burn-in testing as indicated above in Table 2.

The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

We claim:

1. A method, comprising:
receiving a first set of parameters associated with a particular die;
determining a health metric for the particular die using a multivariate analysis of the first set of parameters, the health metric incorporating at least one performance metric;
determining at least one of a market segment designator or a testing plan associated with the particular die based on the health metric.

2. The method of claim 1, further comprising testing the particular die in accordance with the testing plan.

3. The method of claim 1, wherein the testing plan specifies burn-in test requirements.

4. The method of claim 3, wherein the burn-in test requirements specify one of a reduced burn-in test or a full burn-in test.

5. The method of claim 1, further comprising:
determining health metrics for a plurality of die on a wafer;
determining if a percentage of the plurality of die have health metrics exceeding a first threshold; and
configuring the testing plan to specify that the plurality of die are to skip burn-in testing responsive to determining that the percentage of the plurality of die have health metrics exceeding the first threshold.

6. The method of claim 1, further comprising:
determining health metrics for a plurality of die on a wafer;
determining if a percentage of the plurality of die have health metrics exceeding a first threshold; and
assigning the plurality of die a common market segment designator responsive to determining that the percentage of the plurality of die have health metrics exceeding the first threshold.

7. The method of claim 1, further comprising:
determining first health metrics for a plurality of die on a wafer;
determining if a percentage of the plurality of die have first health metrics exceeding a first threshold; and
determining second health metrics for each die in the plurality by incorporating health data associated with neighboring die into the first health metrics responsive to determining that the percentage of the plurality of die have first health metrics does not exceed the first threshold.

8. The method of claim 1, wherein the performance metric comprises at least one of a speed metric, a leakage metric, and a minimum voltage metric.

9. The method of claim 1, wherein the health metric incorporates at least one non-yield performance component and at least one yield component.

10. The method of claim 1, further comprising determining the health metric using at least one of a principal component analysis model, a recursive principal component analysis model, and a k-nearest neighbor model.

11. A method, comprising:
receiving a first set of parameters associated with a particular die;
determining a health metric for the particular die using a multivariate analysis of the first set of parameters;
determining a market segment designator for the particular die based on the health metric.

12. The method of claim 11, further comprising:
determining health metrics for a plurality of die on a wafer;
determining if a percentage of the plurality of die have health metrics exceeding a first threshold; and
assigning the plurality of die a common market segment designator responsive to determining that the percentage of the plurality of die have health metrics exceeding the first threshold.

13. The method of claim 11, further comprising installing the particular die into a system matching the market segment designator.

14. The method of claim 11, wherein the health metric incorporates at least one of a speed metric, a leakage metric, and a minimum voltage metric.

15. The method of claim 11, wherein the health metric incorporates at least one non-yield performance component and at least one yield component.

16. The method of claim 11, further comprising determining the health metric using at least one of a principal component analysis model, a recursive principal component analysis model, and a k-nearest neighbor model.

17. A method, comprising:
receiving a first set of parameters associated with a particular die;
determining a health metric for the particular die using a multivariate analysis of the first set of parameters, the health metric incorporating at least one performance metric;
determining a testing plan associated with the particular die based on the health metric.

18. The method of claim 17, further comprising testing the particular die in accordance with the testing plan.

19. The method of claim 17, wherein the testing plan specifies burn-in test requirements.

20. The method of claim 19, wherein the burn-in test requirements specify one of a reduced burn-in test or a full burn-in test.

21. The method of claim 17, further comprising:
determining first health metrics for a plurality of die on a wafer;
determining if a percentage of the plurality of die have first health metrics exceeding a first threshold; and
determining second health metrics for each die in the plurality of die by incorporating health data associated with neighboring die into the first health metrics responsive to determining that the percentage of the plurality of die have first health metrics does not exceed the first threshold.

22. The method of claim 17, wherein the performance metric comprises at least one of a speed metric, a leakage metric, and a minimum voltage metric.

23. The method of claim 17, wherein the health metric incorporates at least one non-yield performance component and at least one yield component.

24. The method of claim 17, further comprising determining the health metric using at least one of a principal component analysis model, a recursive principal component analysis model, and a k-nearest neighbor model.
